(19) United States
(12) Patent Application Publication
(10) Pub. No.: US 2025/0287511 A1
(43) Pub. Date: Sep. 11, 2025

(54) PROCESS FOR MANUFACTURING A PRINTED CIRCUIT BOARD AND PRINTED CIRCUIT BOARD

(71) Applicant: SAFRAN ELECTRONICS & DEFENSE, PARIS (FR)

(72) Inventors: Patrice CHETANNEAU, MOISSY CRAMAYEL (FR); Bruno LEFEVRE, MOISSY CRAMAYEL (FR); François GUILLOT, MOISSY CRAMAYEL (FR)

(21) Appl. No.: 18/858,120

(22) PCT Filed: Apr. 12, 2023
(86) PCT No.: PCT/FR2023/050523

§ 371 Date: Oct. 18, 2024

(30) Foreign Application Priority Data
Apr. 21, 2022 (FR) 2203705

(51) Int. Cl. H05K 3/24; B33Y 80/00; H05K 1/02; H05K 1/18; H05K 3/00

(52) U.S. Cl. CPC H05K 3/24; B33Y 80/00; H05K 1/0265; H05K 1/185; H05K 3/0044; H05K 2201/10166

(57) ABSTRACT

A process for manufacturing a printed circuit board, the processing including depositing a conductive material, by an additive-manufacturing device, on a first conductive track that a first layer of the printed circuit board initially has, the process further including cutting beforehand, in a second layer of the printed circuit board, a shape complementary to the deposit of conductive material, and pressing the first layer against the second layer.

### TECHNICAL FIELD OF THE INVENTION

The present invention is concerned with a method for manufacturing a printed circuit board especially provided with a first layer including a first series of conductive tracks for power current circulation and a second series of conductive tracks for control current circulation. The invention thus pertains to the field of printed circuit board manufacture.

### TECHNOLOGICAL BACKGROUND OF THE INVENTION

Conventional electronic architectures are provided with several electronic boards connected to each other or via a motherboard. These conventional electronic architectures are gradually evolving towards simplified electronic architectures including a single electronic board. This single electronic board thus embeds both power functions, for example of the power supply or actuation type, and digital functions, for example of the signal processing and computation type.

Merging digital and power functions on a single electronic board does, however, pose issues. One major issue is at the Printed Circuit Board (PCB). Indeed, mixing digital and power functions requires the printed circuit board to include small cross-section conductive tracks for digital functions, enabling numerous fine tracks to be made, and large cross-section conductive tracks for the power functions, enabling high currents to be carried.

At present, methods for manufacturing make it possible to produce conductive tracks having uniform thickness in a same layer of the printed circuit board. The usual solution consists of segregating the digital and power functions per layer of the printed circuit board. Thus, layers with thick conductive tracks are used to carry high currents, while layers with thin conductive tracks are used to carry low currents.

This solution has one major limitation. Indeed, plated-through holes made in the thickness of the printed circuit board, which enable the different superimposed layers to be interconnected, impose a limited thickness of the printed circuit board for reasons relating to the quality and reliability of connections between the different layers of tracks, especially plated-through holes. This thickness of the printed circuit board is usually limited to 3.2 mm. The thickness of the dielectrics separating the conductive tracks then leads to a limitation in the number of layers of conductive tracks.

### SUMMARY OF THE INVENTION

The invention offers a solution to the problems previously discussed, by providing a method for manufacturing a printed circuit board that optimises routing of conductive tracks.

In this context, the invention is thus concerned, in its broadest sense, with a method for manufacturing a printed circuit board.

The method according to this aspect of the invention includes a step of depositing a conductive material, by means of an additive manufacturing device, onto a first conductive track initially present in a first layer of the printed circuit board.

By virtue of the manufacturing method according to this aspect of the invention, it is possible to locally depositing copper or another conductive material on top of a conductive track made with traditional methods. The method according to this aspect of the invention thus makes it possible to make, on one and the same layer of the printed circuit board, conductive tracks with different thicknesses, of low thickness for low currents and high thickness for high currents. This facilitates routing of the conductive tracks and limits the number of layers of the printed circuit board.

Furthermore, the method according to the invention makes it possible to restrain thickness of the printed circuit board and to obtain plated-through holes of moderate length with high quality and reliability.

Further to the characteristics just discussed in the previous paragraph, the method according to this aspect of the invention may have one or more additional characteristics from among the following, considered individually or according to any technically possible combinations.

According to a non-limiting aspect of the invention, the method includes the steps of:
Pre-cutting, in a second layer of the printed circuit board, a complementary shape to the deposition of conductive material,
pressing the first layer with the second layer so that the deposition of conductive material is positioned in the complementary shape precut.

According to a non-limiting aspect of the invention, the deposition of conductive material has a thickness of between 5 μm and 500 μm.

According to a non-limiting aspect of the invention, the conductive material deposited by the additive manufacturing device on the first conductive track is different from the conductive material included in the first conductive track initially present on the first layer of the printed circuit board.

Another aspect of the invention relates to a printed circuit board obtained by a manufacturing method according to any of the aforementioned aspects of the invention.

According to a non-limiting aspect of the invention, the printed circuit board includes an electronic component provided with:
first connection means for power current circulation, said first connection means being connected to the first conductive track having received the deposition of conductive material, and
second connection means for control current circulation, said second connection means being connected to a second conductive track included in the first layer, said second conductive track having a thickness less than a thickness of said first conductive track having received the deposition of conductive material.

According to a non-limiting aspect of the invention, the electronic component is a power transistor.

According to a non-limiting aspect of the invention, the electronic component is disposed in a cavity of a layer for receiving said electronic component, said receiving layer and said electronic component being covered with the first layer.

According to a non-limiting aspect of the invention, the first conductive track having received the deposition of conductive material has a thickness greater than or equal to 70 μm and the second conductive track has a thickness less than or equal to 35 μm.

The invention and its different applications will be better understood upon reading the following description and upon examining the accompanying figures.

### BRIEF DESCRIPTION OF THE FIGURES

FIG. 1 shows a diagram of steps of a non-limiting embodiment of a method for manufacturing a printed circuit board according to one aspect of the invention.

FIG. 2 schematically illustrates a printed circuit board made by implementing the method according to the invention.

FIG. 3 schematically shows another example of a printed circuit board made by implementing the method according to the invention.

### DETAILED DESCRIPTION

The figures are set forth by way of indicating and in no way limiting purposes of the invention.

Unless otherwise specified, a same element appearing in different figures has a single reference.

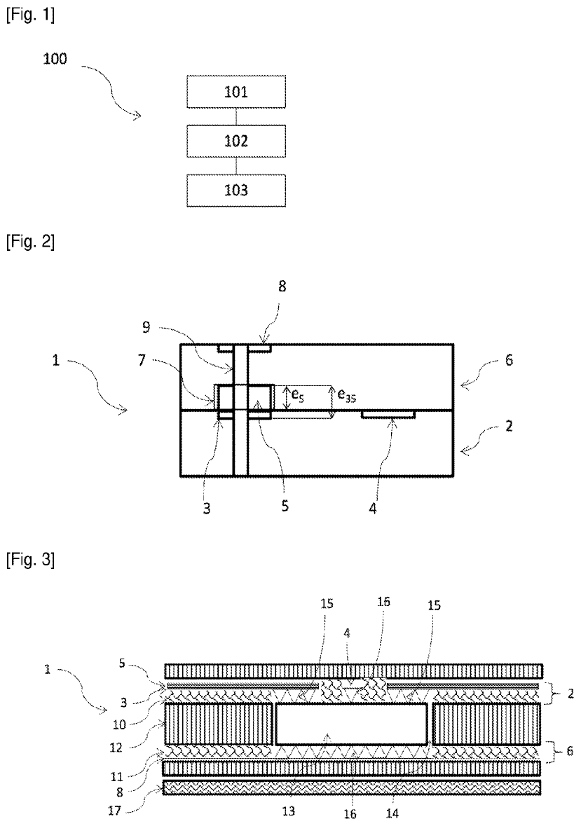

FIG. 1 illustrates a diagram of steps of a non-limiting embodiment of a method for manufacturing a printed circuit board according to one aspect of the invention. FIG. 2 schematically shows a printed circuit board obtained by means of the method according to the invention. For the remainder of the description, reference will be made to FIGS. 1 and 2.

Starting from a printed circuit board 1 initially comprising a first layer 2 (formed of a dielectric material having the function of insulating and securing conductive tracks) provided with a first conductive track 3 and a second conductive track 4 made by means of a traditional method, the method 100 includes a step 101 of depositing a conductive material 5, by means of an additive manufacturing device, onto the first conductive track 3 initially included in the first layer 2 of the printed circuit board 1.

This additive manufacturing device is also known as a three-dimensional printer. By way of a non-limiting example, mention may be made of a device for additive manufacturing on a powder bed or by powder spraying.

This deposition of conductive material 5 makes it possible to increase thickness e35 of the first conductive track 3. Thus, this first conductive track 3 having received the deposition of conductive material 5 can be used for power current circulation, in other words high intensity currents. In a non-limiting example, a current is said to be of high intensity when it is greater than 5A.

The second conductive track 4, which has not received the deposition of conductive material 5, can be used for control current circulation, in other words low-intensity currents. In a non-limiting example, a current is said to be of low intensity when it is less than 5A.

In a non-limiting implementation, the material of the first conductive track 3 is copper and the conductive material 5 deposited by the additive manufacturing device is also copper.

In a different implementation, the material of the first conductive track 3 is copper and the conductive material 5 deposited by the additive manufacturing device is a conductive material different from copper.

In a non-limiting implementation, the deposited conductive material 5 has a thickness e5 of between 5 μm and 500 μm, for example 182 μm.

In a non-limiting embodiment, the method 100 further includes a step of pre-cutting 102, in a second layer 6, formed of a dielectric material, of the printed circuit board 1, a complementary shape 7 to the deposition of conductive material 5.

Thus, the deposition of conductive material 5 can be inserted into the complementary shape 7.

To this end, the method 100 further includes a step of pressing 103 the first layer 2 with the second layer 6 so that the deposition of conductive material 5 is positioned in the complementary shape 7 precut.

In this non-limiting exemplary embodiment, the second layer 6 of the printed circuit board 1 includes a third conductive track 8.

The printed circuit board 1 further includes a plated-through hole 9 passing through the first layer 2 and the second layer 6 to electrically connect the first conductive track 3 with the third conductive track 8.

FIG. 3 schematically shows another example of a printed circuit board 1 according to a non-limiting aspect of the invention obtained via the method according to the invention.

The printed circuit board 1 according to this aspect of the invention includes a first layer 2 provided with a first conductive track 3 covered with a deposition of conductive material 5 and a second conductive track 4. This first layer 2 also includes a dielectric material 10 for electrically insulating the first conductive track 3 covered with the deposition of conductive material 5 and the second conductive track 4. This dielectric material 10 may consist of a glass fabric and an unpolymerised resin prior to manufacture of the printed circuit board 1. After manufacture, this resin is polymerised.

The printed circuit board 1 also includes a second layer 6 provided with a third conductive track 8.

This second layer 6 also includes a dielectric material 11 for electrically insulating the third conductive track 8. This dielectric material 11 may also consist of a glass fabric and a resin which has not been polymerised prior to manufacture of the printed circuit board. After manufacture, this resin is polymerised.

The printed circuit board 1 further includes a layer 12 for receiving an electronic component 13. The material constituting this receiving layer 12 is also a dielectric material. This dielectric material may, for example, consist of a glass fabric and a polymerised resin.

In this exemplary embodiment, the electronic component 13 is disposed in a pre-cut cavity 14 of the receiving layer 12 of the electronic component 13.

In this exemplary embodiment, the receiving layer 12 and the electronic component 13 are disposed between the first layer 2 and the second layer 6 of the printed circuit board 1.

In a non-limiting exemplary embodiment, the electronic component 13 is a gallium nitride power transistor.

In this non-limiting exemplary embodiment, the electronic component 13 is provided with:
first connection means 15 for power current circulation, the first connection means 15 being connected to the first conductive track 3 having received the deposition of conductive material 5; to this end each of the first connection means 15 is for example connected to a plating via or a hole filled with a conductive material passing through the first conductive track 3, and
second connection means 16 for control current circulation, the second connection means 16 being connected to the second and third conductive tracks 4, 8 included respectively in the first layer 2 and the second layer 6; to this end, each of the second connection means 16 is for example connected to a plating via or a hole filled with a conductive material passing through the second or third conductive tracks 4, 8.

It is appropriate to remind that the second conductive track 4 and the third conductive track 8 have a thickness less than a thickness of the first conductive track 3 having received the deposition of conductive material 5.

In a non-limiting exemplary embodiment, the first conductive track 3 having received the deposition of conductive material 5 has a thickness greater than or equal to 70 μm.

In a non-limiting exemplary embodiment, the second conductive track 4 and the third conductive track 8 each have a thickness less than or equal to 35 μm.

Furthermore, in this non-limiting exemplary embodiment, the printed circuit board has a heat dissipation layer 17. This heat dissipation layer is disposed below the second layer 6 and enables heat emitted by the electronic component 13 to be dissipated.

The different aspects of the invention mentioned above have many advantages. These include:
Locally providing a greatly increased thickness of conductive material;
Allowing, on one and the same layer of a printed circuit board, conductive tracks of different thicknesses;
Restraining the thickness of the printed circuit board, which makes it possible to obtain plated-through holes of moderate length.

It should be noted that the person skilled in the art is able to provide alternatives to the aforesaid aspects of the invention, for example by providing a different thickness of deposition of conductive material.

1. A method for manufacturing a printed circuit board comprising a step of depositing a conductive material, by an additive manufacturing device, onto a first conductive track initially present in a first layer of said printed circuit board, the deposition step making it possible to increase thickness of the first conductive track, said method further comprising:
pre-cutting, in a second layer of the printed circuit board, a complementary shape to the deposition of conductive material,
pressing the first layer with said second layer so that the deposition of conductive material is positioned in said complementary shape precut.

2. The method according to claim 1, wherein the deposition of conductive material has a thickness of between 5 μm and 500 μm.

3. The method according to claim 1, wherein the conductive material deposited by the additive manufacturing device on the first conductive track is different from the conductive material included in the first conductive track initially present on the first layer of the printed circuit board.

4. A printed circuit board obtained by a method for manufacturing a printed circuit board according to claim 1, any of the preceding including an electronic component provided with:
first connection means for power current circulation, said first connection means being connected to the first conductive track having received the deposition of conductive material, and
second connection means for control current circulation, said second connection means being connected to a second conductive track, said second conductive track having a thickness less than a thickness of said first conductive track having received the deposition of conductive material,
wherein the first layer includes the second conductive track.

5. The printed circuit board according to claim 4, wherein the electronic component is a power transistor.

6 The printed circuit board according to claim 5, wherein the electronic component is disposed in a cavity of a layer for receiving said electronic component, said receiving layer and said electronic component being covered with the first layer.

7. The printed circuit board according to claim 5, wherein the first conductive track having received the deposition of conductive material has a thickness greater than or equal to 70 μm and the second conductive track has a thickness less than or equal to 35 μm.
